(19) United States
(12) Patent Application Publication
(10) Pub. No.: US 2015/0171320 A1
(43) Pub. Date: Jun. 18, 2015

(54) MEMORY DEVICE

(71) Applicant: Kabushiki Kaisha Toshiba, Minato-ku (JP)

(72) Inventors: Kiyohito Nishihara, Mie-ken (JP); Masumi Saitoh, Kanagawa-ken (JP)

(73) Assignee: Kabushiki Kaisha Toshiba, Minato-ku (JP)

(21) Appl. No.: 14/206,567

(22) Filed: Mar. 12, 2014

Related U.S. Application Data
(60) Provisional application No. 61/917,503, filed on Dec. 18, 2013.

(51) Int. Cl. H01L 45/00

(52) U.S. Cl. CPC H01L 45/1233; H01L 45/1206; H01L 45/1253

(57) ABSTRACT

According to one embodiment, a memory device includes a plurality of first interconnects extending in a first direction, and having divided portions formed respectively in the first interconnects at mutually-different positions in the first direction, a plurality of semiconductor members, each of the semiconductor members being disposed to extend over the first interconnects, a first insulating film disposed to cause each of the semiconductor members to be respectively connected to each of the first interconnects between portions of the first interconnects on two sides of the divided portions and to cause each of the semiconductor members to be insulated from other one of the first interconnects, a second insulating film provided on the semiconductor members, an electrode provided on the second insulating film, a memory cell member provided on the first interconnects, and a second interconnect provided on the memory cell member.

### CROSS-REFERENCE TO RELATED APPLICATIONS

This application is based upon and claims the benefit of priority from U.S. Provisional Patent Application 61/917,503, filed on Dec. 18, 2013; the entire contents of which are incorporated herein by reference.

### FIELD

Embodiments described herein relate generally to a memory device.

### BACKGROUND

In recent years, a cross-point memory device in which a two-terminal memory cell member is connected between an interconnect extending in a first direction and an interconnect extending in a second direction has been proposed. In such a memory device, there are cases where switching elements are interposed at the interconnects.

### BRIEF DESCRIPTION OF THE DRAWINGS

FIG. 1 is a plan view illustrating the memory device according to a first embodiment;

FIG. 2A is a cross-sectional view along line A-A′ shown in FIG. 1; FIG. 2B is a cross-sectional view along line B-B′ shown in FIG. 1; FIG. 2C is a cross-sectional view along line C-C′ shown in FIG. 1; FIG. 2D is a cross-sectional view along line D-D′ shown in FIG. 1; and FIG. 2E is a cross-sectional view along line E-E′ shown in FIG. 1;

FIG. 3 is a plan view illustrating one of the semiconductor members and the region around the one of the semiconductor members according to the first embodiment;

FIG. 4A is a plan view illustrating a method for manufacturing the memory device according to the first embodiment; FIG. 4B is a cross-sectional view along line A-A′ shown in FIG. 4A; and FIG. 4C is a cross-sectional view along line B-B′ shown in FIG. 4A;

FIG. 5A is a plan view illustrating a method for manufacturing the memory device according to the first embodiment; FIG. 5B is a cross-sectional view along line A-A′ shown in FIG. 5A; and FIG. 5C is a cross-sectional view along line B-B′ shown in FIG. 5A;

FIG. 6A and FIG. 6B are cross-sectional views illustrating the method for manufacturing the memory device according to the first embodiment;

FIG. 7A is a plan view illustrating the method for manufacturing the memory device according to the first embodiment; and FIG. 7B is a cross-sectional view along line A-A′ shown in FIG. 7A;

FIG. 8A, FIG. 8B, and FIG. 8C are cross-sectional views illustrating the method for manufacturing the memory device according to the first embodiment;

FIG. 9 is a plan view illustrating a memory device according to a second embodiment;

FIG. 10A is a cross-sectional view along line A-A′ shown in FIG. 9; FIG. 10B is a cross-sectional view along line B-B′ shown in FIG. 9; FIG. 10C is a cross-sectional view along line C-C′ shown in FIG. 9; FIG. 10D is a cross-sectional view along line D-D′ shown in FIG. 9; and FIG. 10E is a cross-sectional view along line E-E′ shown in FIG. 9;

FIG. 11 is a plan view illustrating a memory device according to a third embodiment;

FIG. 12A is a cross-sectional view along line A-A′ shown in FIG. 11; FIG. 12B is a cross-sectional view along line B-B′ shown in FIG. 11; FIG. 12C is a cross-sectional view along line C-C′ shown in FIG. 11; FIG. 12D is a cross-sectional view along line D-D′ shown in FIG. 11; and FIG. 12E is a cross-sectional view along line E-E′ shown in FIG. 11;

FIG. 13 is a plan view illustrating a memory device according to a fourth embodiment;

FIG. 14A is a plan view illustrating one of the semiconductor members of a fifth embodiment and the region around the one of the semiconductor members; and FIG. 14B is a cross-sectional view along line A-A′ shown in FIG. 14A;

FIG. 15 is a plan view illustrating a memory device according to a sixth embodiment;

FIG. 16 is a cross-sectional view along line A-A′ shown in FIG. 15; and

FIG. 17 is a cross-sectional view illustrating a memory device according to a seventh embodiment.

### DETAILED DESCRIPTION

According to one embodiment, a memory device includes a plurality of first interconnects extending in a first direction, and having divided portions formed respectively in the plurality of first interconnects at mutually-different positions in the first direction, a plurality of semiconductor members, each of the plurality of semiconductor members being disposed to extend over the plurality of first interconnects, a first insulating film disposed to cause each of the semiconductor members to be respectively connected to each of the first interconnects between portions of the first interconnects on two sides of the divided portions and to cause each of the semiconductor members to be insulated from other one of the first interconnects, a second insulating film provided on the semiconductor members, an electrode provided on the second insulating film, a memory cell member provided on the first interconnects, and a second interconnect provided on the memory cell member.

Various embodiments will be described hereinafter with reference to the accompanying drawings.

### First Embodiment

First, a first embodiment will be described.

A memory device according to the embodiment is a nonvolatile memory device, and more specifically, a resistance random access memory device having a cross-point structure.

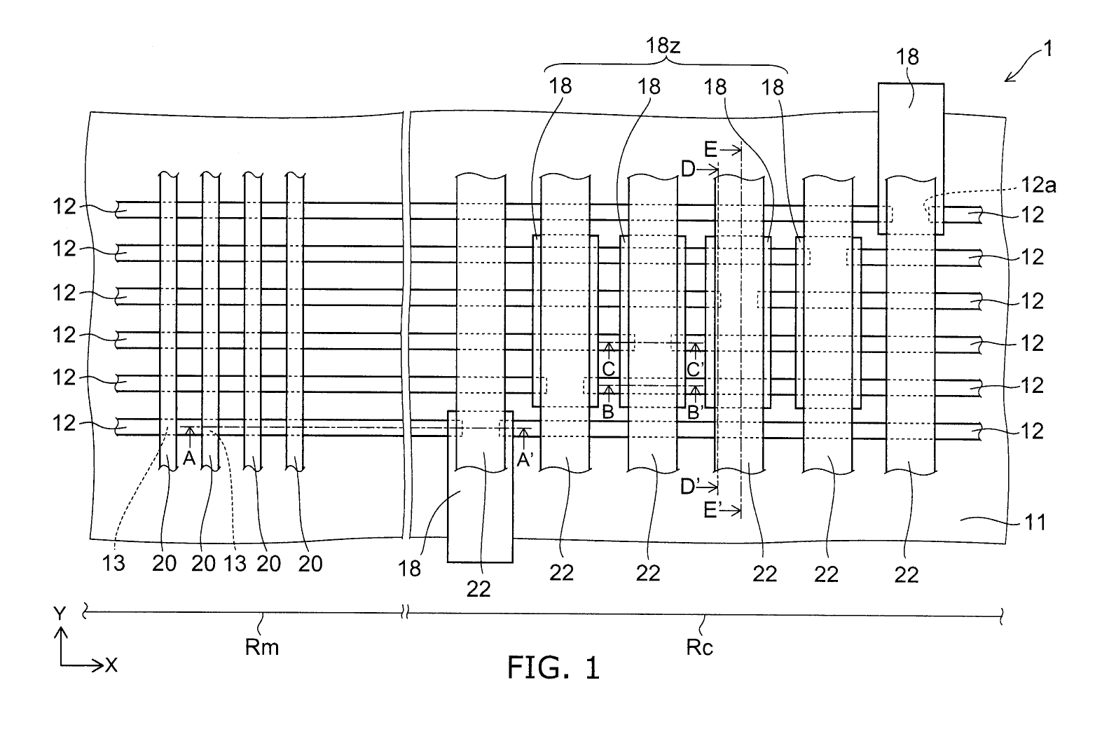

FIG. 1 is a plan view illustrating the memory device according to the embodiment.

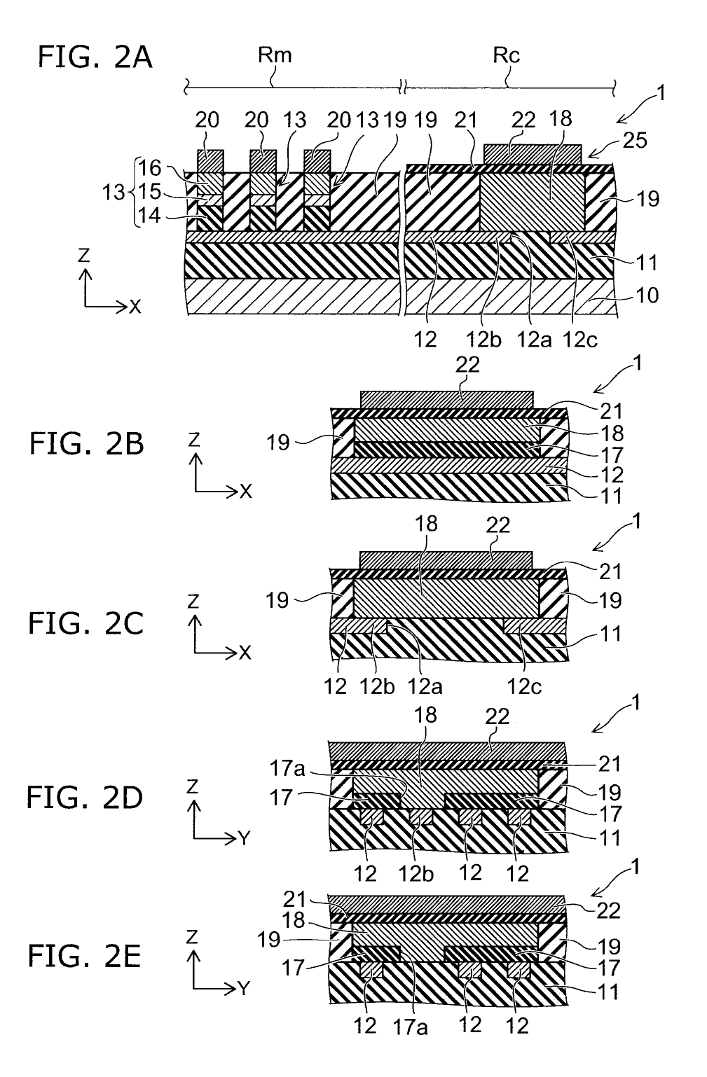

FIG. 2A is a cross-sectional view along line A-A′ shown in FIG. 1; FIG. 2B is a cross-sectional view along line B-B′ shown in FIG. 1; FIG. 2C is a cross-sectional view along line C-C′ shown in FIG. 1; FIG. 2D is a cross-sectional view along line D-D′ shown in FIG. 1; and FIG. 2E is a cross-sectional view along line E-E′ shown in FIG. 1.

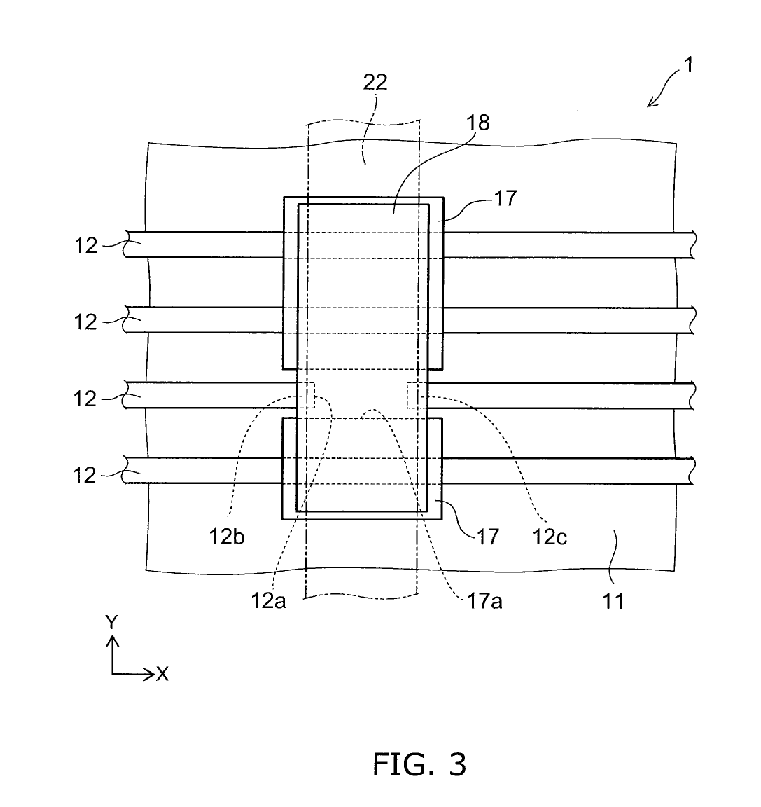

FIG. 3 is a plan view illustrating one of the semiconductor members and the region around the one of the semiconductor members.

As shown in FIG. 1, FIG. 2A to FIG. 2E, and FIG. 3, a semiconductor substrate 10 that is made of, for example, silicon is provided in the memory device 1 according to the embodiment. A memory cell region Rm and a peripheral circuit region Rc are set at the upper surface of the semiconductor substrate 10.

An inter-layer insulating film 11 is provided on the semiconductor substrate 10. The inter-layer insulating film 11 is formed of, for example, silicon oxide. Multiple word lines 12 are provided at the upper layer portion of the inter-layer insulating film 11 to extend in one direction (hereinbelow, called the “X-direction”) parallel to the upper surface of the inter-layer insulating film 11. The word lines 12 are formed of, for example, tungsten (W) or molybdenum (Mo).

A divided portion 12a is made at one location of each of the word lines 12 in the peripheral circuit region Rc. A portion of the inter-layer insulating film 11 is disposed inside the divided portion 12a. Portions 12b and 12c of the word line 12 on the two sides of the divided portion 12a are separated from each other by the divided portion 12a. The divided portions 12a of the multiple word lines 12 are at mutually-different positions in the X-direction. Hereinbelow, a direction parallel to the upper surface of the inter-layer insulating film 11 and orthogonal to the X-direction is called the “Y-direction;” and a direction orthogonal to both the X-direction and the Y-direction, i.e., the vertical direction, is called the “Z-direction.”

In the memory cell region Rm, multiple memory cell members 13 are provided on each of the word lines 12. When viewed from the Z-direction, the memory cell members 13 are arranged in a matrix configuration along the X-direction and the Y-direction. The configuration of each of the memory cell members 13 is a pillar configuration extending in the Z-direction; and a resistance change layer 14, a metal supply layer 15, and a stopper layer 16 are stacked in order from the lower side in each of the memory cell members 13. The resistance change layer 14 is formed of, for example, polysilicon. The metal supply layer 15 is formed of a metal that is capable of moving through the resistance change layer 14, e.g., silver (Ag), copper (Cu), nickel (Ni), aluminum (Al), or titanium (Ti). The stopper layer 16 is formed of, for example, tungsten (W).

In the peripheral circuit region Rc, an insulating film 17 is selectively provided between the word lines 12, which are arranged periodically and parallel to each other, and multiple semiconductor members 18, which are provided to extend over the regions directly above the multiple word lines 12. Thereby, each of the semiconductor members 18 has a width corresponding to the arrangement region of the multiple word lines 12 and is selectively connected to only one word line 12.

This will now be described in detail. The insulating film 17 is selectively provided above the inter-layer insulating film 11 and the word lines 12. The insulating film 17 is formed of, for example, silicon oxide. The insulating film 17 is provided on a portion of (n−1) word lines 12 of n word lines 12 (n being an integer not less than 2) that are consecutively arranged along the Y-direction. In the embodiment, n is, for example, 4. Also, the insulating film 17 is not provided on the divided portion 12a of one of the word lines 12 or the portions 12b and 12c on the two sides of the divided portion 12a of the one of the word lines 12 to make an opening 17a.

The multiple semiconductor members 18 are provided on the insulating film 17. The semiconductor members 18 are formed of a semiconductor material, e.g., silicon that substantially does not include an impurity. The configurations of all of the semiconductor members 18 are the same, e.g., a rectangular parallelepiped having the Y-direction as the longitudinal direction. Each of the semiconductor members 18 is disposed to extend over the n word lines 12 consecutively arranged along the Y-direction.

Also, each of the semiconductor members 18 is disposed in the region directly above the divided portion 12a of the one of the word lines 12 disposed inside the opening 17a, in the region directly above the portions 12b and 12c on the two sides of the divided portion 12a of the one of the word lines 12, and in the region directly above the insulating film 17. Thereby, each of the semiconductor members 18 is connected between the portion 12b and the portion 12c of the one of the word lines 12 via the opening 17a of the insulating film 17, and is insulated from the other word lines 12 by the insulating film 17. In other words, the insulating film 17 is interposed between the word lines 12 and the semiconductor members 18 and is disposed to cause each of the semiconductor members 18 to be connected respectively to each of the word lines 12 between the portion 12b and the portion 12c of the word line 12 and to cause each of the semiconductor members 18 to be insulated from the other word lines 12.

Also, the semiconductor members 18 that are connected to mutually-different word lines 12 are disposed at mutually-different positions in the X-direction. For example, the positions in the X-direction of the divided portions 12a of the multiple word lines 12 arranged in one direction along the Y-direction are arranged in one direction along the X-direction. Thereby, the n semiconductor members 18 that are connected to the consecutively-arranged n word lines 12 are consecutively arranged in the X-direction. In the embodiment, a set 18z is formed for every n semiconductor members 18 consecutively arranged in the X-direction; and the n semiconductor members 18 that belong to the set 18z are disposed at the same position in the Y-direction.

An inter-layer insulating film 19 is provided above the inter-layer insulating film 11 and the word line 12. The inter-layer insulating film 19 is formed of, for example, silicon oxide. The inter-layer insulating film 19 is disposed between the memory cell members 13, between the semiconductor members 18, and between the memory cell members 13 and the semiconductor members 18. The inter-layer insulating film 19 covers the side surfaces of the memory cell member 13 and the semiconductor member 18 side surfaces but does not cover the upper surface of the memory cell member 13 or the upper surface of the semiconductor member 18. In FIG. 1 and FIG. 3, the inter-layer insulating film 19 is not shown for easier viewing of the drawings.

In the memory cell region Rm, multiple bit lines 20 are provided on the inter-layer insulating film 19 and the memory cell members 13 to extend in the Y-direction. The bit lines 20 are formed of, for example, tungsten or molybdenum. Each of the bit lines 20 passes through a region directly above the memory cell members 13 arranged in one column along the Y-direction. Thereby, the memory cell members 13 are connected between the word lines 12 and the bit lines 20.

In the peripheral circuit region Rc, a gate insulating film 21 is provided on the inter-layer insulating film 19 and the semiconductor member 18. The gate insulating film 21 is formed of, for example, silicon oxide. The gate insulating film 21 covers the upper surface of the semiconductor member 18. In FIG. 1 and FIG. 3, the gate insulating film 21 is not shown for easier viewing of the drawings.

A gate electrode 22 that extends in the Y-direction is provided on the gate insulating film 21. The gate electrode 22 covers the upper surface of the semiconductor member 18 with the gate insulating film 21 interposed. In other words, the gate insulating film 21 is disposed between the multiple semiconductor members 18 and the multiple gate electrodes 22. As described below, the gate electrode 22 and the bit lines 20 are formed by patterning the same conductive film. Accordingly, the composition of the gate electrode 22 is equal to the composition of the bit lines 20; and the thickness of the gate electrode 22 is equal to the thickness of the bit lines 20. In FIG. 3, the gate electrodes 22 are illustrated by double dot-dash lines for easier viewing of the drawing.

A method for manufacturing the memory device according to the embodiment will now be described.

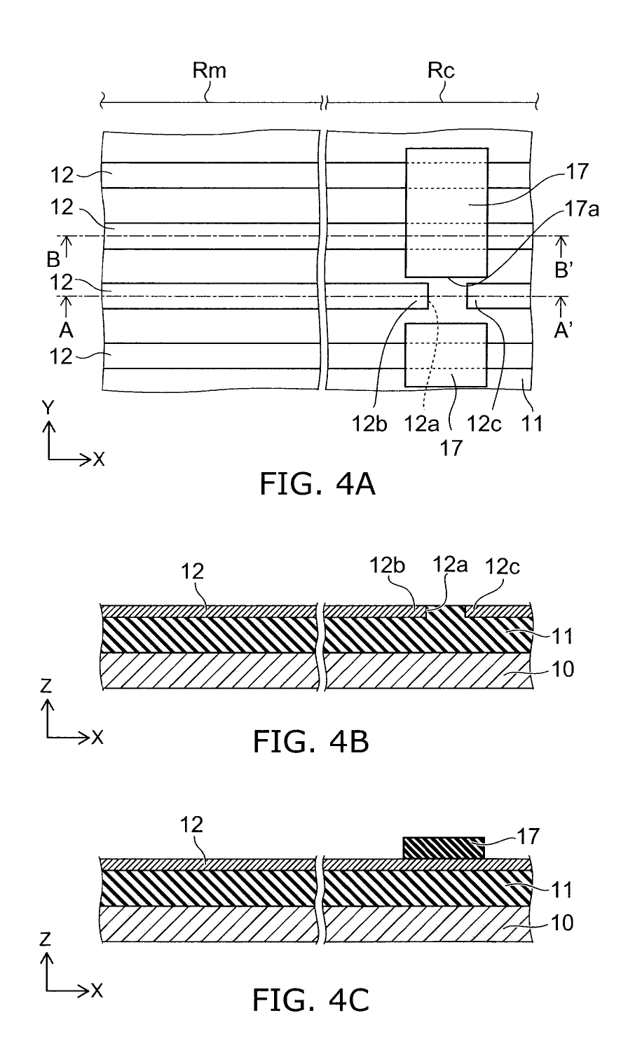

FIG. 4A is a plan view illustrating the method for manufacturing the memory device according to the embodiment; FIG. 4B is a cross-sectional view along line A-A′ shown in FIG. 4A; and FIG. 4C is a cross-sectional view along line B-B′ shown in FIG. 4A.

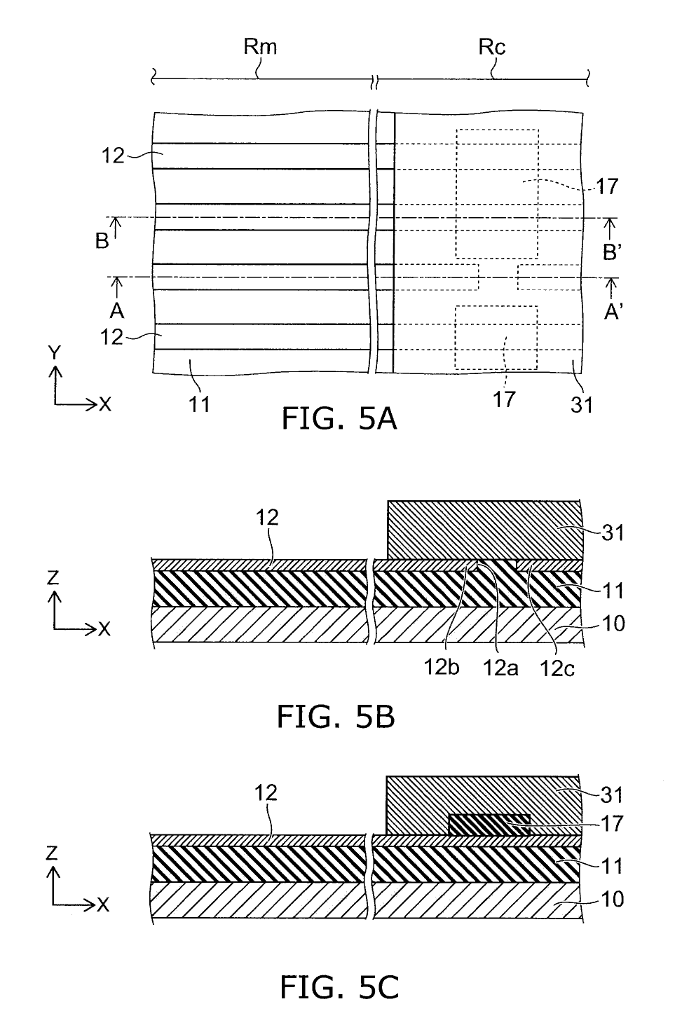

FIG. 5A is a plan view illustrating the method for manufacturing the memory device according to the embodiment; FIG. 5B is a cross-sectional view along line A-A′ shown in FIG. 5A; and FIG. 5C is a cross-sectional view along line B-B′ shown in FIG. 5A.

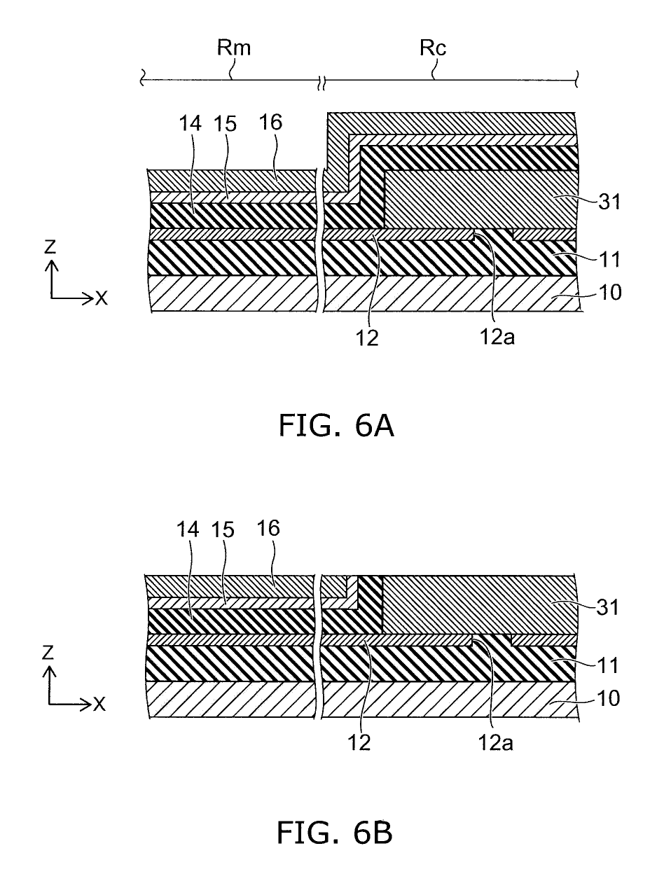

FIG. 6A and FIG. 6B are cross-sectional views illustrating the method for manufacturing the memory device according to the embodiment.

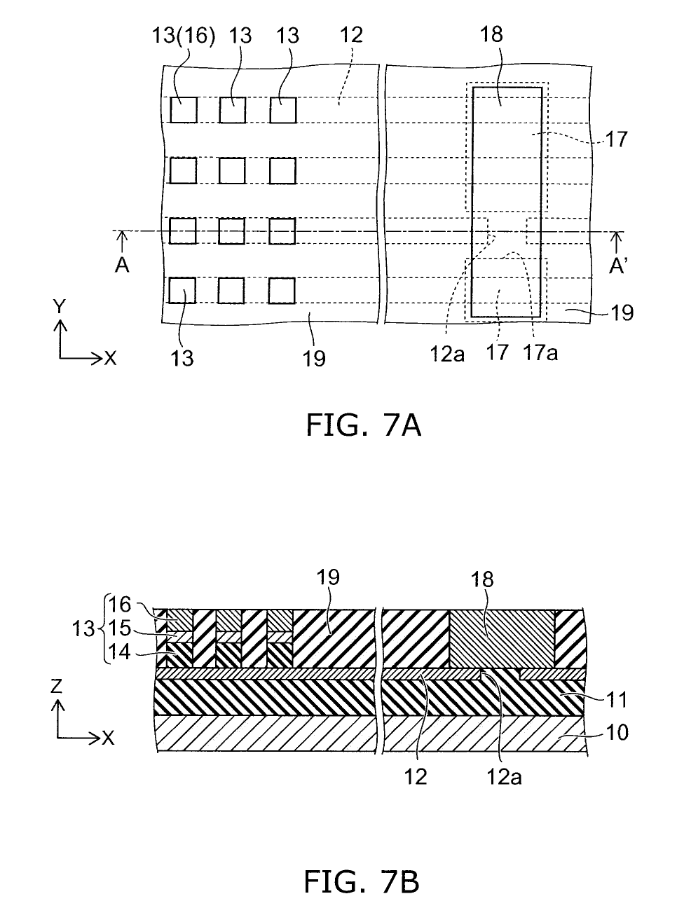

FIG. 7A is a plan view illustrating the method for manufacturing the memory device according to the embodiment; and FIG. 7B is a cross-sectional view along line A-A′ shown in FIG. 7A.

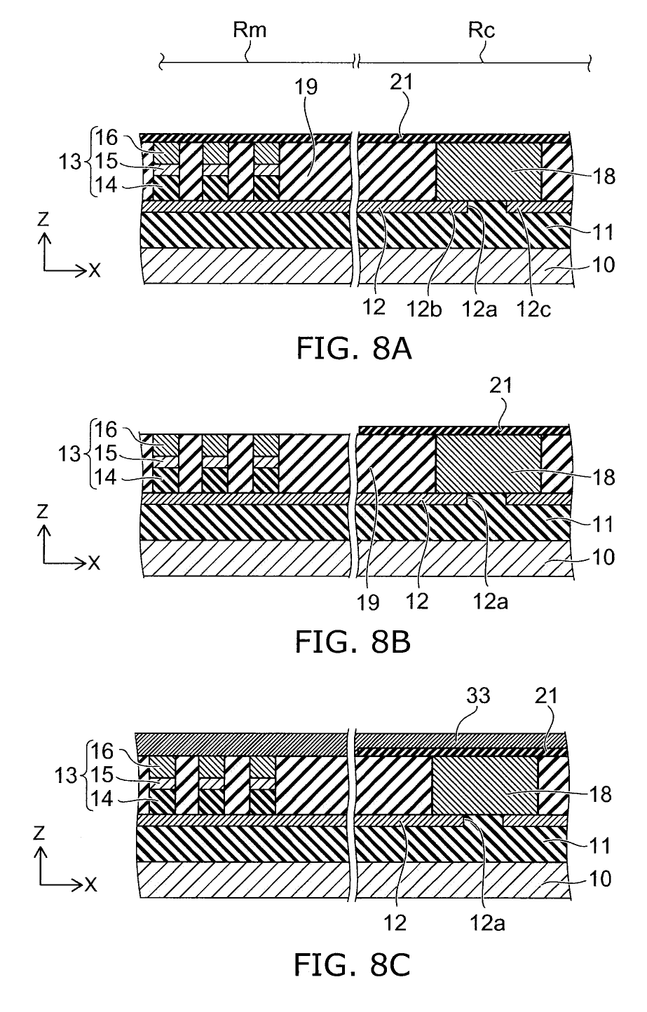

FIG. 8A, FIG. 8B, and FIG. 8C are cross-sectional views illustrating the method for manufacturing the memory device according to the embodiment.

First, the semiconductor substrate 10 is prepared as shown in FIG. 4A to FIG. 4C. The memory cell region Rm and the peripheral circuit region Rc are set at the upper surface of the semiconductor substrate 10. Then, the inter-layer insulating film 11 and the multiple word lines 12 are formed on the semiconductor substrate 10. The word line 12 is disposed to extend in the X-direction at the upper layer portion of the inter-layer insulating film 11; and the divided portion 12a is made at one location inside the peripheral circuit region Rc. The position of the divided portion 12a in the X-direction is different between the word lines 12. For example, the positions of the divided portions 12a of the multiple word lines 12 arranged in order along the Y-direction are arranged in order along the X-direction.

Then, the insulating film 17 is selectively formed above the inter-layer insulating film 11 and the word lines 12. The insulating film 17 is formed to cover a portion of (n−1) (e.g., 3) word lines 12 of the n (e.g., 4) word lines 12 consecutively arranged along the Y-direction but not to cover the divided portion 12a of one of the word lines 12 and the portions 12b and 12c on the two sides of the divided portion 12a of the one of the word lines 12.

Then, as shown in FIG. 5A to FIG. 5C, a silicon film 31 is formed in the peripheral circuit region Rc by depositing silicon, which does not have an added impurity, above the inter-layer insulating film 11, the word lines 12, and the insulating film 17 and by selectively removing the silicon.

Then, as shown in FIG. 6A, the resistance change layer 14, the metal supply layer 15, and the stopper layer 16 are formed in this order on the entire surface. At this time, the resistance change layer 14, the metal supply layer 15, and the stopper layer 16 extend onto the silicon film 31 in the peripheral circuit region Rc.

Then, as shown in FIG. 6B, planarization is performed by CMP (chemical mechanical polishing), etc., using the portion of the stopper layer 16 disposed in the memory cell region Rm as a stopper. Thereby, the stopper layer 16, the metal supply layer 15, and the resistance change layer 14 that are on the silicon film 31 are removed.

Then, as shown in FIG. 7A and FIG. 7B, the multiple memory cell members 13 are formed at portions in regions directly above the word lines 12 by selectively removing the stopper layer 16, the metal supply layer 15, and the resistance change layer 14; and the silicon film 31 is selectively removed to be patterned into the multiple semiconductor members 18. Each of the semiconductor members 18 is formed in the region directly above the insulating film 17 and is formed in the regions directly above the divided portion 12a of one of the word lines 12 disposed inside the opening 17a and the portion 12b and the portion 12c on the two sides of the divided portion 12a of the one of the word lines 12. Then, the inter-layer insulating film 19 is filled between the memory cell members 13, between the semiconductor members 18, and between the memory cell members 13 and the semiconductor members 18 by depositing an insulating material on the entire surface and performing CMP using the stopper layer 16 as a stopper.

Then, as shown in FIG. 8A, the gate insulating film 21 is formed on the entire surface. At this time, the gate insulating film 21 covers the upper surfaces of the semiconductor members 18.

Then, as shown in FIG. 8B, the gate insulating film 21 is removed from the memory cell region Rm.

Then, as shown in FIG. 8C, a conductive film 33 is formed on the entire surface.

Then, the conductive film 33 is selectively removed as shown in FIG. 1 and FIG. 2A to FIG. 2E. Thereby, the bit lines 20 are formed in the memory cell region Rm to extend in the Y-direction and pass through the regions directly above the memory cell members 13. On the other hand, in the peripheral circuit region Rc, the gate electrode 22 is formed to extend in the Y-direction and pass through the regions directly above the semiconductor members 18. Thus, the memory device 1 is manufactured.

Operations of the memory device 1 according to the embodiment will now be described.

For one of the memory cell members 13, by applying a positive voltage such that the bit line 20 becomes positive and the word line 12 becomes negative, a portion of the metal atoms, e.g., the silver atoms, included in the metal supply layer 15 becomes positive ions and moves into the resistance change layer 14. Then, the positive ions bond with electrons supplied from the word line 12 and precipitate as metal atoms. Thereby, a filament (not shown) is formed inside the resistance change layer 14; and the state is switched to a low resistance state (an on-state). Also, by applying a reverse voltage such that the bit line 20 becomes negative and the word line 12 becomes positive, at least a portion of the metal atoms of the filament becomes positive ions and returns to the metal supply layer 15. Thereby, the filament is broken; and the resistance change layer 14 is switched to a high resistance state (an off-state). The memory device 1 stores data corresponding to the resistance states of the resistance change layer 14.

On the other hand, a field effect transistor 25 is formed of the word line 12, the semiconductor member 18, the gate insulating film 21, and the gate electrode 22. In the transistor 25, the portion 12b and the portion 12c of the word line 12 function as source/drains; and the semiconductor member 18 functions as a channel. The gate-length direction of the transistor 25 is the X-direction.

Then, the timing of applying the potential to the word line 12 is controlled by the transistor 25. In other words, by applying the positive potential to the gate electrode 22, electrons collect in a portion of the semiconductor member 18 positioned at the vicinity of the gate electrode 22 to become carriers. Thereby, a current flows in the semiconductor member 18; and the transistor 25 is switched to the on-state. As a result, the word line 12 conducts; and a potential is applied to the memory cell member 13.

Effects of the embodiment will now be described.

In the embodiment, the source/drains of the transistors 25 are formed by utilizing the word lines 12 for integrating the memory cell members 13 in a cross-point configuration. Also, the gate electrode 22 of the transistors 25 is formed simultaneously with the bit lines 20 by patterning the conductive film 33. Thereby, an increase of the number of processes for forming the transistors 25 is suppressed; and the memory device 1 can be formed inexpensively.

Also, in the embodiment, the width, i.e., the length in the Y-direction, of the semiconductor member 18 is wider than the width of the word line 12. Thereby, compared to the case where the width of the semiconductor member 18 is about the same as the width of the word line 12, the width of the channel is wider; and the on-state current of the transistor 25 can be increased. As a result, the drive current for driving the memory cell member 13 increases.

Further, in the embodiment, the positions of the divided portions 12a in the X-direction are different from each other. Thereby, the positions of the semiconductor members 18 in the X-direction can be different from each other. Also, the insulating film 17 is interposed between the word lines 12 and the semiconductor members 18; and one of the word lines 12 is connected to one of the semiconductor members 18. Also, one of the semiconductor members 18 corresponds to one of the gate electrodes 22.

As a result, the word lines 12 can be connected one-to-one to the semiconductor members 18 even in the case where the width of the semiconductor member 18 is set to be a width that covers the arrangement region of multiple word lines 12 in a state in which the word lines 12 are formed periodically to extend in linear configurations in the X-direction and the gate electrodes 22 are formed periodically to extend in linear configurations in the Y-direction. Thereby, a complex draw-out of the word lines 12 and the gate electrodes 22 is unnecessary even in the case where the current driving capability of the transistor 25 is increased by increasing the width of the semiconductor member 18; and in the Y-direction, the size of the peripheral circuit region Rc can be about the same as the size of the memory cell region Rm. As a result, an increase of the surface area of the peripheral circuit region Rc can be suppressed; and downsizing of the memory device 1 can be realized.

### Second Embodiment

A second embodiment will now be described.

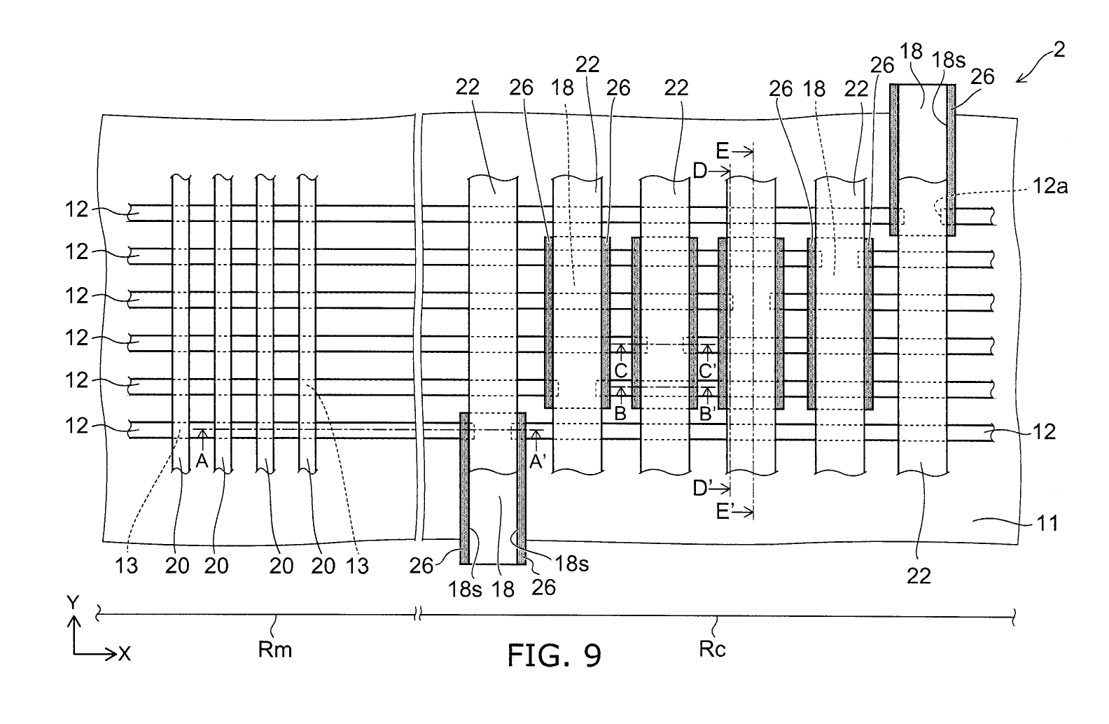

FIG. 9 is a plan view illustrating a memory device according to the embodiment.

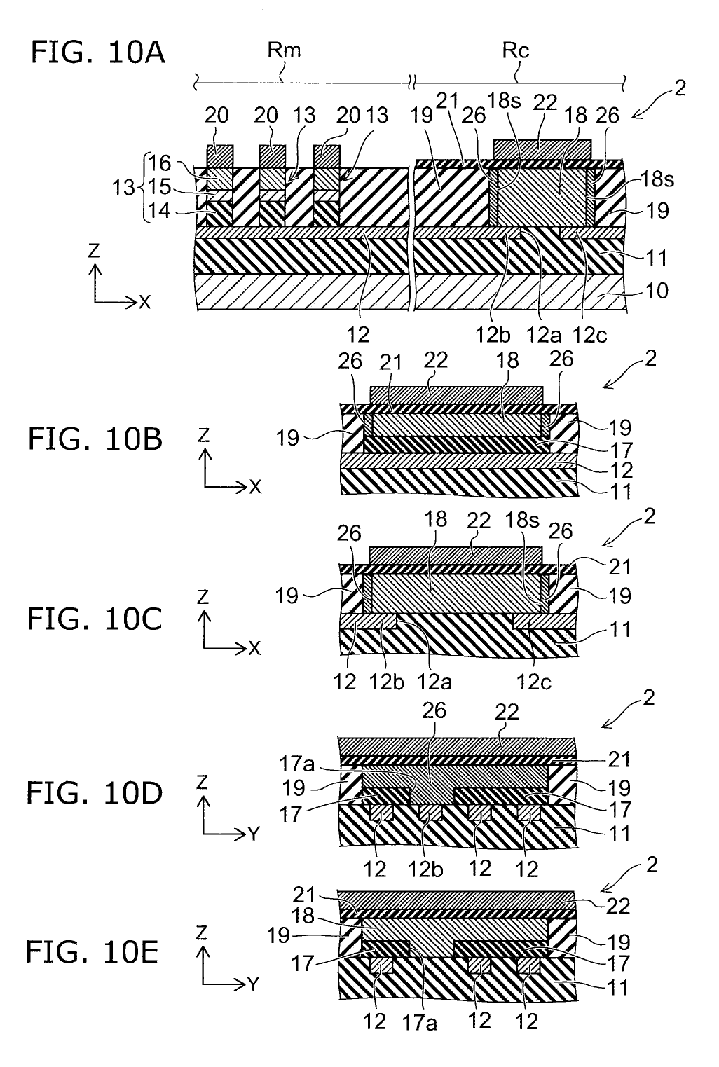

FIG. 10A is a cross-sectional view along line A-A′ shown in FIG. 9; FIG. 10B is a cross-sectional view along line B-B′ shown in FIG. 9; FIG. 10C is a cross-sectional view along line C-C′ shown in FIG. 9; FIG. 10D is a cross-sectional view along line D-D′ shown in FIG. 9; and FIG. 10E is a cross-sectional view along line E-E′ shown in FIG. 9.

The insulating film 17, the inter-layer insulating film 19, and the gate insulating film 21 are not shown for easier viewing of the drawing in FIG. 9.

In the memory device 2 according to the embodiment as shown in FIG. 9 and FIG. 10A to FIG. 10E, a conductive layer 26 is provided on two side surfaces 18s of each of the semiconductor members 18 facing the X-direction. The conductive layer 26 contacts the side surfaces 18s.

For example, the semiconductor member 18 is formed of polysilicon that substantially does not contain an impurity. Also, the conductive layer 26 is formed of a metal silicide, e.g., a silicide of tungsten (W), titanium (Ti), cobalt (Co), nickel (Ni), etc.

Operations and effects of the embodiment will now be described.

According to the embodiment, the current that flows into the semiconductor member 18 can be spread in the Y-direction and the Z-direction by the conductive layer 26 because the conductive layer 26 is provided on the side surfaces 18s facing the direction in which the current flows in the semiconductor member 18, i.e., the X-direction. Thereby, the current can be caused to flow by effectively utilizing the cross-sectional area of the YZ cross section of the semiconductor member 18; and the current driving capability of the transistor 25 improves even further.

Otherwise, the configuration, the manufacturing method, the operations, and the effects of the embodiment are similar to those of the first embodiment described above.

### Third Embodiment

A third embodiment will now be described.

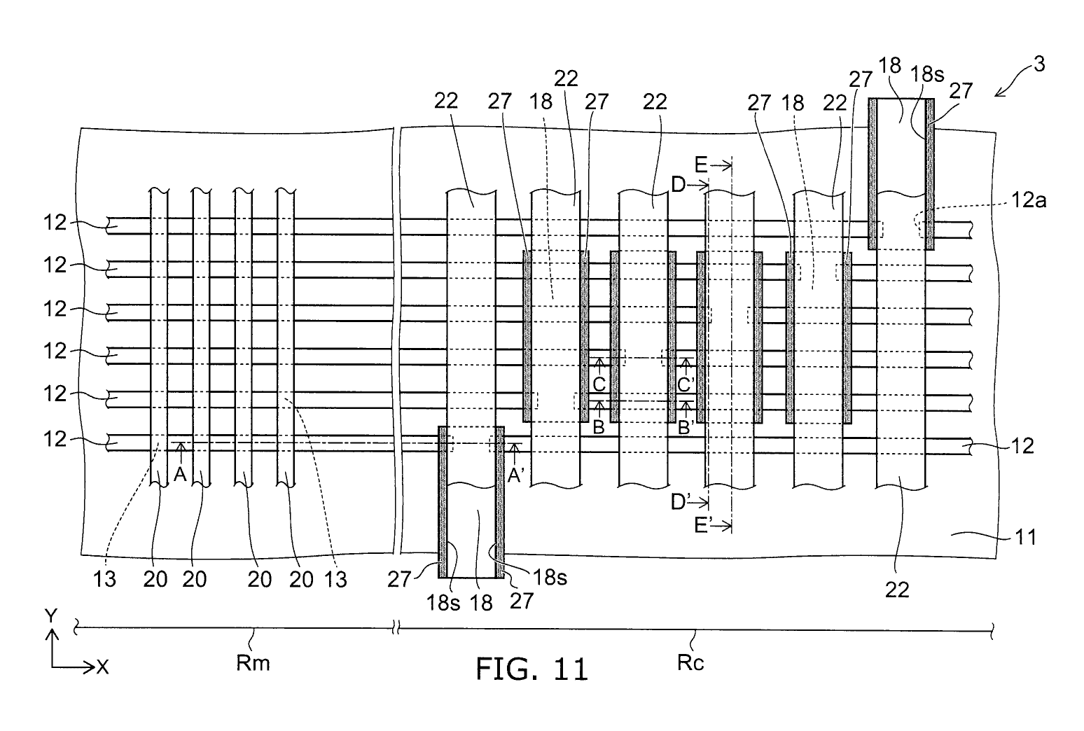

FIG. 11 is a plan view illustrating a memory device according to the embodiment.

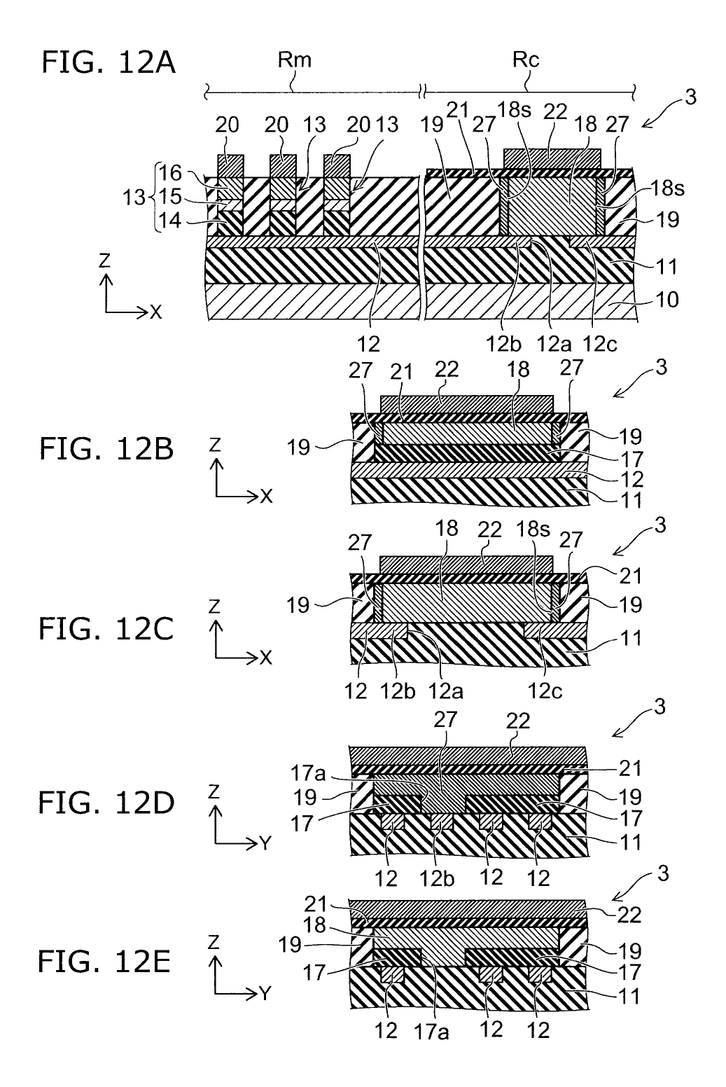

FIG. 12A is a cross-sectional view along line A-A′ shown in FIG. 11; FIG. 12B is a cross-sectional view along line B-B′ shown in FIG. 11; FIG. 12C is a cross-sectional view along line C-C′ shown in FIG. 11; FIG. 12D is a cross-sectional view along line D-D′ shown in FIG. 11; and FIG. 12E is a cross-sectional view along line E-E′ shown in FIG. 11.

The insulating film 17, the inter-layer insulating film 19, and the gate insulating film 21 are not shown for easier viewing of the drawing in FIG. 11.

In the memory device 3 according to the embodiment as shown in FIG. 11 and FIG. 12A to FIG. 12E, a semiconductor layer 27 is provided on the two side surfaces 18s of each of the semiconductor members 18 facing the X-direction. The semiconductor layer 27 contacts the side surfaces 18s. The semiconductor layer 27 is made of an n-type or p-type semiconductor material that includes an impurity such as phosphorus, boron, etc.

For example, the semiconductor member 18 is formed of polysilicon that substantially does not contain an impurity. Also, the semiconductor layer 27 is formed by implanting an impurity such as phosphorus, boron, etc., in the side surfaces 18s of the semiconductor member 18. Accordingly, the semiconductor layer 27 is formed as a single body with the semiconductor member 18 at the two end portions of the semiconductor member 18.

Operations and effects of the embodiment will now be described.

According to the embodiment, the semiconductor layer 27 functions as the source/drain layers of the transistor 25. Thereby, the transistor 25 can be operated more stably; and the current driving capability of the transistor 25 can be improved.

Otherwise, the configuration, the manufacturing method, the operations, and the effects of the embodiment are similar to those of the first embodiment described above.

### Fourth Embodiment

A fourth embodiment will now be described.

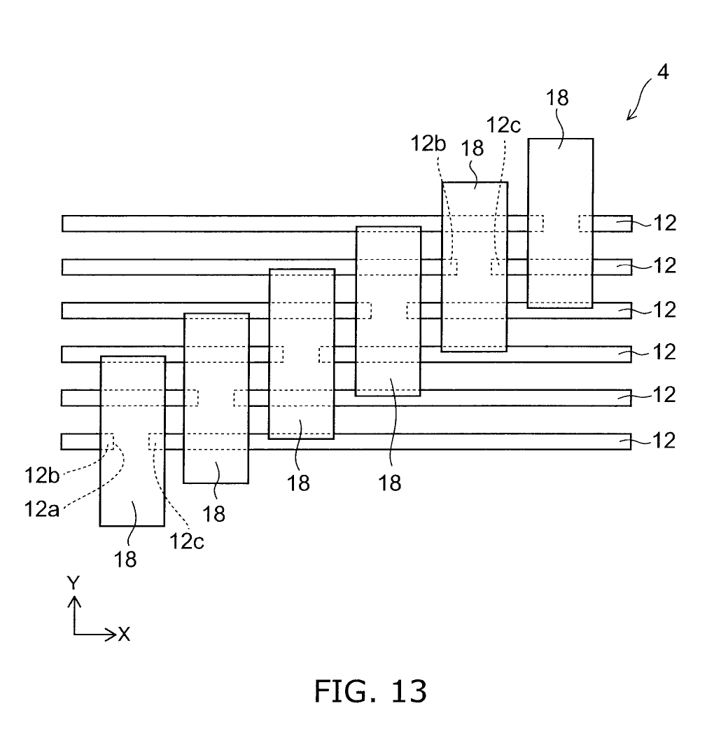

FIG. 13 is a plan view illustrating a memory device according to the embodiment.

For convenience of illustration, only the word lines 12 and the semiconductor members 18 are shown in FIG. 13.

As shown in FIG. 13, the positional relationship between one of the word lines 12 and the semiconductor member 18 connected between the portion 12b and the portion 12c of the word line 12 of the memory device 4 according to the embodiment is different from that of the memory device 1 (referring to FIG. 1) according to the first embodiment described above. In other words, in the memory device 4 according to the embodiment, the word line 12 is disposed at the center of the semiconductor member 18 in the Y-direction. In other words, each of the semiconductor members 18 is connected between the portion 12b and the portion 12c of one of the word lines 12 at the Y-direction central portion of the semiconductor member 18.

Operations and effects of the embodiment will now be described.

According to the embodiment, the current that flows into the semiconductor member 18 from the word line 12 spreads easily to the entire width of the semiconductor member 18 because the word line 12 is connected to the width-direction central portion of the semiconductor member 18. Also, the fluctuation of the characteristics that is due to the position where the word line 12 is connected to the semiconductor member 18 does not occur. Thereby, the current driving capability can be made uniform between the transistors 25; and the average current driving capability of the transistors 25 can be improved.

Otherwise, the configuration, the manufacturing method, the operations, and the effects of the embodiment are similar to those of the first embodiment described above.

### Fifth Embodiment

A fifth embodiment will now be described.

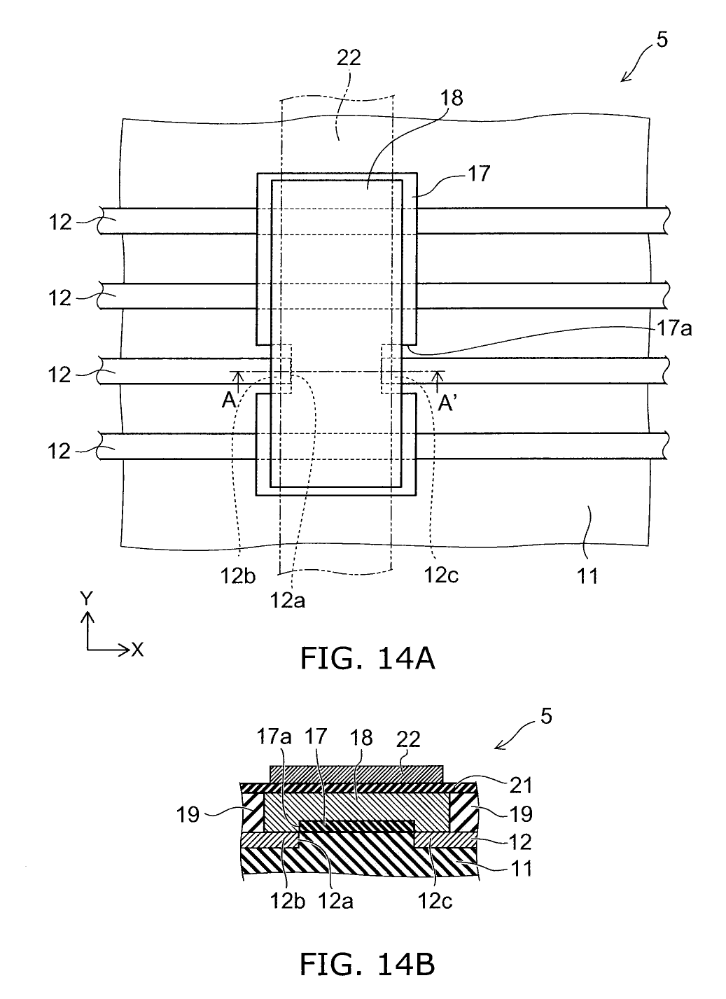

FIG. 14A is a plan view illustrating one of the semiconductor members of the embodiment and the region around the one of the semiconductor members; and FIG. 14B is a cross-sectional view along line A-A′ shown in FIG. 14A.

For easier viewing of the drawing in FIG. 14A, the insulating film 17, the inter-layer insulating film 19, and the gate insulating film 21 are not shown; and the gate electrode 22 is illustrated by a double dot-dash line.

In a memory device 5 according to the embodiment as shown in FIG. 14A and FIG. 14B, the insulating film 17 is provided also in the region directly above the divided portion 12a of the word line 12. Thereby, the insulating film 17 is disposed at the gate-length direction (the X-direction) central portion of the lower portion of the semiconductor member 18. Similarly to the first embodiment described above, the insulating film 17 is not provided in the regions directly above the portions 12b and 12c of the word line 12; and the portion 12b and the portion 12c contact the semiconductor member 18.

Operations and effects of the embodiment will now be described.

In the embodiment, the insulating film 17 is provided at the gate-length-direction central portion of the lower portion of the semiconductor member 18. Thereby, the portion of the semiconductor member 18 where the controllability by the gate electrode 22 is weak can be reduced; and the leak current when OFF can be suppressed.

Otherwise, the configuration, the manufacturing method, the operations, and the effects of the embodiment are similar to those of the first embodiment described above.

### Sixth Embodiment

A sixth embodiment will now be described.

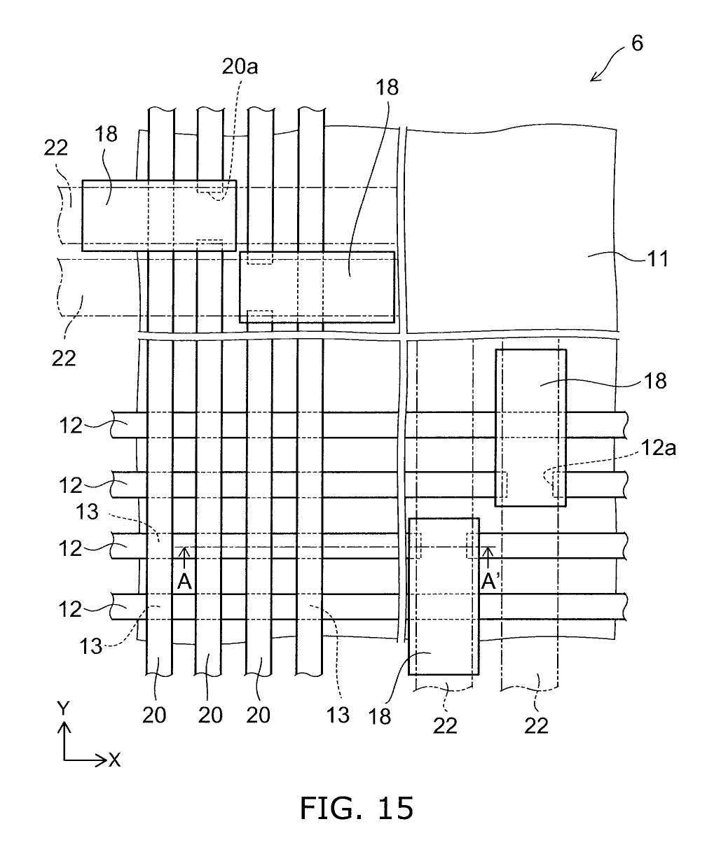

FIG. 15 is a plan view illustrating a memory device according to the embodiment.

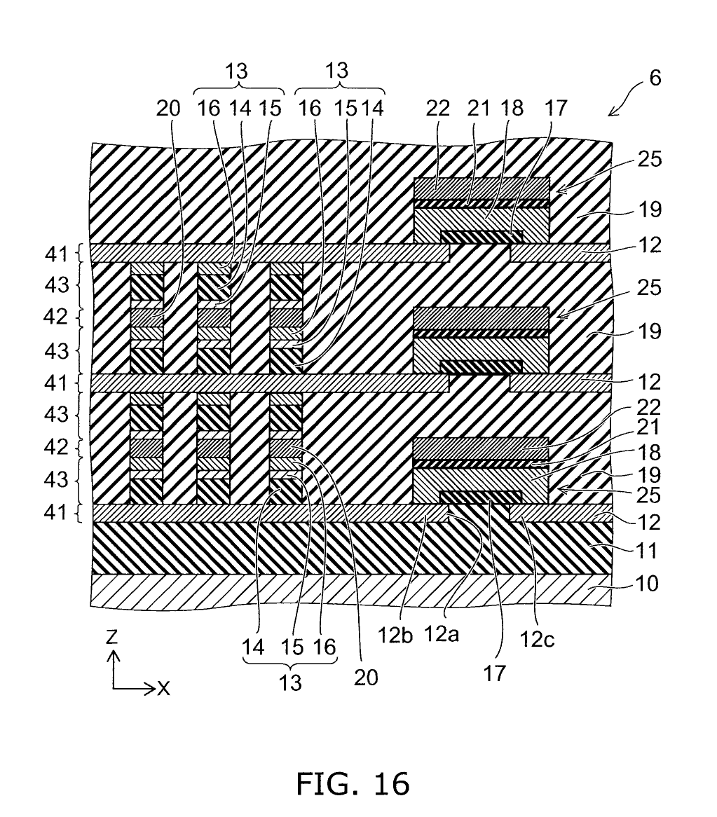

FIG. 16 is a cross-sectional view along line A-A′ shown in FIG. 15.

For easier viewing of the drawing in FIG. 15, the insulating film 17, the inter-layer insulating film 19, and the gate insulating film 21 are not shown; and the gate electrodes 22 are illustrated by double dot-dash lines.

In the memory device 6 according to the embodiment as shown in FIG. 15 and FIG. 16, multiple levels of the structure described in the first embodiment described above are stacked along the Z-direction.

Specifically, a word line interconnect layer 41 that is made of the multiple word lines 12 arranged on the same XY plane and a bit line interconnect layer 42 that is made of the multiple bit lines 20 arranged on the same XY plane are arranged alternately along the Z-direction to be separated from each other. Also, a memory cell layer 43 that is made of the multiple memory cell members 13 arranged on the same XY plane is disposed between the word line interconnect layer 41 and the bit line interconnect layer 42. The memory cell member 13 that has a pillar configuration is connected between each of the word lines 12 and each of the bit lines 20.

The configurations of the bit line interconnect layer 42 of the lowermost layer and the structural body below the bit line interconnect layer 42 of the lowermost layer are similar to those of the memory device 1 (referring to FIG. 1 and FIG. 2A to FIG. 2E) according to the first embodiment described above. However, in the embodiment, similarly to the fifth embodiment described above, the insulating film 17 is provided also in the region directly above the divided portion 12a of the word line 12.

Also, the structure of the portion in which the word line interconnect layer 41, the memory cell layer 43, and the bit line interconnect layer 42 are consecutively arranged in order from the lower layer side is similar to the structure of the memory device 1 according to the first embodiment excluding the semiconductor substrate 10 and the inter-layer insulating film 11.

On the other hand, in the structure of the portion in which the bit line interconnect layer 42, the memory cell layer 43, and the word line interconnect layer 41 are consecutively arranged in order from the lower layer side, the stacking order inside each of the memory cell members 13 and the formation position of the transistor 25 are different from those of the configuration of the memory device 1.

Specifically, in the memory cell members 13 belonging to the memory cell layer 43 for which the bit line interconnect layer 42 is disposed below and the word line interconnect layer 41 is disposed above, the metal supply layer 15, the resistance change layer 14, and the stopper layer 16 are arranged in order from the lower layer side. In other words, in each of the memory cell members 13, the stopper layer 16 is disposed in the uppermost layer; and the metal supply layer 15 is disposed further on the bit line 20 side than is the resistance change layer 14.

Also, in the memory cell layers 43 for which the word line interconnect layer 41 is disposed above, the transistor 25 is formed to be interposed at the bit line 20. In other words, a divided portion 20a is made in the bit line 20; the semiconductor member 18 is provided to straddle the divided portion 20a; and the gate insulating film 21 and the gate electrode 22 are provided on the semiconductor member 18. Other than the gate-length direction being the Y-direction, the configuration of the transistor 25 interposed at the bit line 20 is similar to the configuration of the transistor 25 interposed at the word line 12 described above. Also, the composition and thickness of the gate electrode 22 of the transistor 25 interposed at the bit line 20 are the same as the composition and thickness of the word line 12 disposed one level above the bit line 20.

Further, in the memory device 6, the layout of the divided portion 12a, the insulating film 17, and the semiconductor member 18 is the same between the word line interconnect layers 41 of each layer. Therefore, as shown in FIG. 16, the formation position of the divided portion 12a in the X-direction is the same between the word lines 12 arranged in the Z-direction.

The memory device 6 according to the embodiment can be manufactured by repeating the manufacturing processes described in the first embodiment described above.

Effects of the embodiment will now be described.

Because the memory cell members 13 can be stacked in the Z-direction in the embodiment, the integration of the memory cell members 13 can be increased.

Also, in the embodiment, the channels of the transistors 25 are formed not in the semiconductor substrate 10 but in the semiconductor members 18. Thereby, the transistors 25 can be formed for each memory cell layer 43. As a result, the transistors 25 also can be stacked upward as the memory cell members 13 are stacked upward. Thereby, even in the case where the number of stacks of the memory cell members 13 increases, the surface area of the peripheral circuit region Rc does not increase; and the surface area occupied by the peripheral circuit region Rc on the chip also does not increase. Accordingly, by stacking the memory cell members 13, higher integration can be realized while suppressing the increase of the surface area for the entire memory device 6.

Otherwise, the configuration, the manufacturing method, the operations, and the effects of the embodiment are similar to those of the first embodiment described above.

### Seventh Embodiment

A seventh embodiment will now be described.

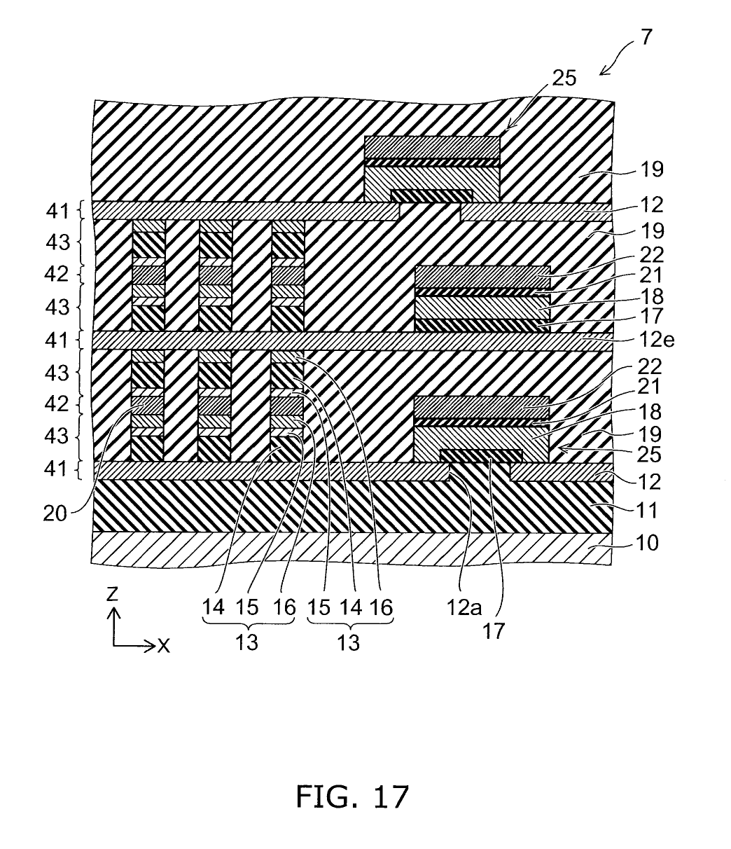

FIG. 17 is a cross-sectional view illustrating a memory device according to the embodiment.

As shown in FIG. 17, compared to the memory device 6 (referring to FIG. 16) according to the sixth embodiment described above, the layout of the divided portion 12a, the insulating film 17, and the semiconductor member 18 is different between the multiple word line interconnect layers 41 in the memory device 7 according to the embodiment.

Thereby, among 3 word lines 12 shown in FIG. 17, the position in the X-direction of the divided portion 12a of the word line 12 of the uppermost layer is different from the position in the X-direction of the divided portion 12a of the word line 12 of the lowermost layer. Also, the divided portion 12a of the word line 12 of the middle level is positioned outside FIG. 17. Also, the semiconductor member 18 that is connected to a word line 12 (not shown) separated in the Y-direction from the word line 12 of the middle level as viewed from the word line 12 of the middle level is shown in FIG. 17. Therefore, the word line 12 of the middle level and the semiconductor member 18 on the word line 12 of the middle level are insulated from each other by the insulating film 17.

Similarly, the layout of the divided portion 20a, the insulating film 17, and the semiconductor member 18 is different between the multiple bit line interconnect layers 42.

Otherwise, the configuration, the manufacturing method, the operations, and the effects of the embodiment are similar to those of the sixth embodiment described above.

According to the embodiments described above, a memory device that is small and has a high current driving capability of the switching elements can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A memory device, comprising:
a plurality of first interconnects extending in a first direction, divided portions being formed respectively in the plurality of first interconnects at mutually-different positions in the first direction;
a plurality of semiconductor members, each of the plurality of semiconductor members being disposed to extend over the plurality of first interconnects;
a first insulating film disposed to cause each of the semiconductor members to be respectively connected to each of the first interconnects between portions of the first interconnects on two sides of the divided portions and to cause each of the semiconductor members to be insulated from other one of the first interconnects;
a second insulating film provided on the semiconductor members;
an electrode provided on the second insulating film;
a memory cell member provided on the first interconnects; and
a second interconnect provided on the memory cell member.

2. The memory device according to claim 1, further comprising a conductive layer contacting a side surface of the semiconductor members facing the first direction.

3. The memory device according to claim 2, wherein
the semiconductor member includes silicon, and
the conductive layer includes a silicide.

4. The memory device according to claim 1, further comprising a semiconductor layer contacting a side surface of the semiconductor members facing the first direction.

5. The memory device according to claim 1, wherein the electrode and the second interconnect extend in a second direction intersecting the first direction.

6. The memory device according to claim 1, wherein
a composition of the electrode is equal to a composition of the second interconnect, and
a thickness of the electrode is equal to a thickness of the second interconnect.

7. The memory device according to claim 1, wherein positions in the first direction of the divided portions of the plurality of first interconnects arranged in one direction are arranged in one direction.

8. The memory device according to claim 1, wherein the configurations of the plurality of semiconductor members are same rectangular parallelepiped.

9. The memory device according to claim 1, wherein positions of the plurality of semiconductor members in a second direction intersecting the first direction are equal to each other.

10. The memory device according to claim 1, wherein the first interconnects are disposed at a center of the semiconductor members connected to the first interconnects in a second direction intersecting the first direction.

11. The memory device according to claim 1, wherein the first insulating film is not provided on the divided portions.

12. The memory device according to claim 1, wherein the first insulating film is provided also on the divided portions.

13. The memory device according to claim 1, wherein the memory cell member includes:
a resistance change layer; and
a metal supply layer including a metal capable of moving through the resistance change layer.

14. The memory device according to claim 13, wherein
the resistance change layer includes silicon, and
the metal is one type of material selected from the group consisting of silver, copper, nickel, aluminum, and titanium.

15. A memory device, comprising:
a plurality of first interconnects extending in a first direction, first divided portions being formed respectively in the plurality of first interconnects at mutually-different positions in the first direction;
a plurality of first semiconductor members, each of the plurality of first semiconductor members being disposed to extend over the plurality of first interconnects;
a first insulating film disposed to cause each of the semiconductor members to be connected respectively to each of the first interconnects between portions of the first interconnects on two sides of the divided portions and to cause each of the semiconductor members to be insulated from other one of the first interconnects;
a first gate insulating film provided on the first semiconductor members;
a first electrode provided on the first gate insulating film;
a first memory cell member provided on the first interconnects;
a plurality of second interconnects provided on the first memory cell member to extend in a second direction intersecting the first direction, second divided portions being formed respectively in the plurality of second interconnects at mutually-different positions in the second direction;
a plurality of second semiconductor members, each of the plurality of second semiconductor members being disposed to extend over the plurality of second interconnects;
a second insulating film disposed to cause each of the second semiconductor members to be connected respectively to each of the second interconnects between portions of the second interconnects on two sides of the second divided portions and to cause each of the second semiconductor members to be insulated from one other of the second interconnects;
a second gate insulating film provided on the second semiconductor members;
a second electrode provided on the second gate insulating film;
a second memory cell member provided on the second interconnects; and
a plurality of third interconnects provided on the second memory cell member to extend in the first direction.

16. The memory device according to claim 15, wherein
a composition of the first electrode is equal to a composition of the second interconnect,
a thickness of the first electrode is equal to a thickness of the second interconnects,
a composition of the second electrode is equal to a composition of the third interconnects, and
a thickness of the second electrode is equal to a thickness of the third interconnects.

17. A memory device, comprising:
a first interconnect extending in a first direction, a first divided portion being formed in the first interconnect;
a second interconnect extending in the first direction, a second divided portion being formed in the second interconnect at a position different from a position of the first divided portion in the first direction;
a first memory cell member provided on the first interconnect;
a second memory cell member provided on the second interconnect;
a third interconnect provided to extend in a second direction intersecting the first direction to pass over the first memory cell member and over the second memory cell member;
a first insulating film provided on a portion of the second interconnect but not provided on first portions of the first interconnect on two sides of the first divided portion;
a second insulating film provided on a portion of the first interconnect but not provided on second portions of the second interconnect on two sides of the second divided portion;
a first semiconductor member provided on the first divided portion, on the first portions, and on the first insulating film to be insulated from the second interconnect by the first insulating film and connected between the first portions;
a second semiconductor member provided on the second divided portion, on the second portions, and on the second insulating film to be insulated from the first interconnect by the second insulating film and connected between the second portions;
a first electrode provided on the first semiconductor member;
a second electrode provided on the second semiconductor member; and
a first gate insulating film provided between the first semiconductor member and the first electrode and between the second semiconductor member and the second electrode.

18. The memory device according to claim 17, wherein
a third divided portion is formed in the third interconnect, the memory device further comprising:
a third memory cell member provided on the first interconnect;
a fourth memory cell member provided on the second interconnect;
a fourth interconnect provided to extend in the second direction to pass over the third memory cell member and the fourth memory cell member, a fourth divided portion being formed in the fourth interconnect at a position different from a position of the third divided portion in the second direction;
a fifth memory cell member and a sixth memory cell member provided on the third interconnect;
a seventh memory cell member and an eighth memory cell member provided on the fourth interconnect;
a fifth interconnect provided to extend in the first direction to pass over the fifth memory cell member and the seventh memory cell member;
a sixth interconnect provided to extend in the first direction to pass over the sixth memory cell member and the eighth memory cell member;
a third insulating film provided on a portion of the fourth interconnect but not provided on third portions of the third interconnect on two sides of the third divided portion;
a fourth insulating film provided on a portion of the third interconnect but not provided on fourth portions of the fourth interconnect on two sides of the fourth divided portion;
a third semiconductor member provided on the third divided portion, on the third portions, and on the third insulating film to be insulated from the fourth interconnect by the third insulating film and connected between the third portions;
a fourth semiconductor member provided on the fourth divided portion, on the fourth portions, and on the fourth insulating film to be insulated from the third interconnect by the fourth insulating film and connected between the fourth portions;
a third electrode provided on the third semiconductor member;
a fourth electrode provided on the fourth semiconductor member; and
a second gate insulating film provided between the third semiconductor member and the third electrode and between the fourth semiconductor member and the fourth electrode.

19. The memory device according to claim 17, further comprising:
a first conductive layer contacting a side surface of the first semiconductor member facing the first direction; and
a second conductive layer contacting a side surface of the second semiconductor member facing the first direction.

20. The memory device according to claim 17, further comprising:
a first semiconductor layer contacting a side surface of the first semiconductor member facing the first direction; and
a second semiconductor layer contacting a side surface of the second semiconductor member facing the first direction.
